(19) United States
(12) Patent Application Publication
(10) Pub. No.: US 2021/0104601 A1
(43) Pub. Date: Apr. 8, 2021

(54) HIGH-VOLTAGE N-CHANNEL HEMT DEVICE

(71) Applicant: University of Electronic Science and Technology of China, Chengdu (CN)

(72) Inventors: Qian LUO, Chengdu (CN); Xuanqing JIANG, Chengdu (CN); Houdong WEN, Chengdu (CN); Siyuan MENG, Chengdu (CN)

(73) Assignee: University of Electronic Science and Technology of China, Chengdu (CN)

(21) Appl. No.: 17/084,665

(22) Filed: Oct. 30, 2020

(30) Foreign Application Priority Data
Oct. 8, 2019 (CN) 201910948348.6

(51) Int. Cl. H01L 29/06; H01L 29/778; H01L 29/66

(52) U.S. Cl. CPC H01L 29/0634; H01L 29/0649; H01L 29/0653; H01L 29/405; H01L 29/66462; H01L 29/0692; H01L 29/7786

(57) ABSTRACT

A high-voltage n-channel high electron mobility transistor (HEMT) device is provided. In view of a relatively high process difficulty in preparing super junctions on heterojunction devices such as HEMT, the high-voltage n-channel HEMT device provides a surface super junction structure for an n-channel HEMT device. A comb-finger-shaped p-type semiconductor strip block is prepared on a surface of a drift region of the high-voltage n-channel HEMT device, and the p-type semiconductor strip block is electrically connected to a source electrode, so that large-range depletion of a channel of the drift region is realized under a turn-off condition, and a depletion region tolerates a high voltage, thus enhancing a breakdown characteristic of the high-voltage re-channel HEMT device.

### CROSS REFERENCE TO THE RELATED APPLICATIONS

This application is based upon and claims priority to Chinese Patent Application No. 201910948348.6, filed on Oct. 8, 2019, the entire contents of which are incorporated herein by reference.

### TECHNICAL FIELD

The present invention belongs to the technical field of a semiconductor power device, and in particular relates to an n-channel HEMT (high electron mobility transistor) device with a comb-finger-shaped p-type surface voltage-resistant structure connected to a source electrode.

### BACKGROUND

In the field of radio frequency and power integrated circuits, with the increasing integration of circuits, the requirements of the circuits on various characteristics of the devices are getting higher and higher. Under the condition that the properties of the traditional silicon devices have almost reached the theoretical limit, it is urgent to develop a new device with properties of high frequency, high speed, high power, low noise, low power consumption and the like, so as to meet the requirements of high-speed and high-capacity computers and high-capacity long-distance communication. Semiconductor heterojunction devices emerge at the right moment. The high electron mobility transistor (HEMT) has attracted wide attention from the industry insiders due to its advantages of ultrahigh speed, low power consumption and the like (especially at low temperature). A basic structure of the HEMT is a modulated doped heterojunction. Taking an n-channel HEMT device as an example, a basic structure of the HEMT device is as shown in FIG. 1, including: a substrate, a buffer layer, a barrier layer and electrodes sequentially from bottom to top. The buffer layer is epitaxially grown on the substrate, and the barrier layer is grown on the buffer layer. The barrier layer may be doped or not according to specific conditions. A source electrode, a gate electrode and a drain electrode are distributed on the barrier layer. Generally, the source electrode and the drain electrode are in ohmic contact with a two-dimensional conductive channel by an alloying method, and the gate electrode is in Schottky contact with the barrier layer. A two-dimensional electronic gas (2-DEG) is present in a triangular potential well which is further formed by a heterojunction interface formed by contact between the buffer layer and the barrier layer. Since the electronic gas is distal from a surface state and is separated from an impurity center on the barrier layer spatially, the electronic gas is not affected by scattering of ionized impurities and has high mobility. A depth and a width of the triangular potential well may be controlled by a gate voltage, so that a concentration of the two-dimensional electronic gas may be changed, thereby controlling HEMT current. In addition, how to increase a breakdown voltage of the device is one of the research focuses in the field. Since the HEMT device is in a working state, an electric field peak formed on edges of the gate electrode and the drain electrode will reduce the breakdown voltage of the device, thereby limiting the maximum output power of the device. Therefore, in order to use the HEMT device as a power device, research on the high-voltage HEMT device is of great significance. In view of this, a variety of voltage-resistant structures have been developed at present, of which a field plate structure is the most common one. However, the field plate structure has high requirement on process precision and has limited improvement on the breakdown voltage of the HEMT, so that the practical application of the field plate is limited. In addition, many researches have considered drawing lessons from the super junction in LDMOS and proposed to introduce a similar super junction in the HEMT. However, the HEMT is a heterojunction epitaxial device and has more limitations in process compared with the traditional Si-based devices, so an existing super junction structure for the HEMT is actually a multi-layer epitaxial structure, and is high in process difficulty and limited in voltage resistance improvement. For this situation, it is very necessary to develop a novel voltage-resistant structure similar to a super junction for HEMPT.

### SUMMARY

In view of the defects in the prior art that a voltage-resistant structure for the HEMT device is high in process difficulty and limited in breakdown voltage improvement, the present invention provides an n-channel HEMT device with a comb-finger-shaped p-type surface voltage-resistant structure connected to a source electrode.

To enhance the voltage-resistant characteristic of the n-channel device, the present invention provides the following technical solution:

a high-voltage n-channel HEMT device includes: a substrate 1, a buffer layer 2 arranged on an upper surface of the substrate 1, a barrier layer 3 arranged on an upper surface of the barrier layer 2, a gate electrode 4 arranged on an upper surface of the barrier layer 3, a source electrode 5 and a drain electrode 6; the buffer layer 2 and the barrier layer 3 form a heterojunction on a contact interface of the buffer layer 2 and the barrier layer 3, and a two-dimensional conductive channel 9 is formed in the heterojunction interface; the source electrode 5 and the drain electrode 6 are arranged on two upper sides of the barrier layer 3 respectively and are in ohmic contact with the two-dimensional conductive channel 9; the gate electrode 4 is arranged on the barrier layer 3 between the source electrode 5 and the drain electrode 6 and is in Schottky contact with the barrier layer 3: characterized in that

the barrier layer 3 between the gate electrode 4 and the drain electrode 6 is provided with a surface voltage-resistant structure which includes a plurality of p-type semiconductor blocks 7 arranged in a comb finger shape, each of the p-type semiconductor blocks 7 extending along gate and drain directions; and the p-type semiconductor blocks 7 arranged in a comb finger shape are not in contact with the gate electrode 4 and the drain electrode 6 and are electrically connected to the source electrode 5, so that the p-type semiconductor blocks 7 arranged in a comb finger shape are connected to the source electrode 5.

Further, an insulating medium 8 is filled at least between the adjacent p-type semiconductor blocks 7.

Further, the insulating medium 8 is in contact with or isolated from the drain electrode 6.

As an implementation, two ends of the insulating medium 8 arranged between the adjacent p-type semiconductor blocks 7 are flush with the p-type semiconductor blocks 7, that is, the p-type semiconductor blocks 7 and the head and tail of the insulating medium 8 are flush along an arrangement direction of the p-type semiconductor blocks 7.

As an implementation, the insulating medium 8 arranged between the adjacent p-type semiconductor blocks 7 may mutually communicate with and semi-surround the p-type semiconductor blocks 7 along an arrangement direction of the p-type semiconductor blocks 7, and the insulating medium 8 is isolated from the drain electrode 6.

As an implementation, the insulating medium 8 arranged between the adjacent p-type semiconductor blocks 7 may extend in a direction of the drain electrode 6 and completely fill a gap between each of the p-type semiconductor blocks 7 and the drain electrode 6, that is, the insulating medium 8 may mutually communicate with and semi-surround the p-type semiconductor blocks 7 along an arrangement direction of the p-type semiconductor block 7, and the insulating medium 8 is in contact with the drain electrode 6.

Further, the surface voltage-resistant structure may be used in combination with a voltage-resistant structure such as a field plate and the like.

The working principle of the device according to the present invention is as follows:

since a p-type surface voltage-resistant structure connected to the drain electrode and distributed in a comb finger shaped is added between the gate electrode and the drain electrode, the p-type semiconductor block can raise an energy band of the barrier layer of the n-channel HEMI, so that a triangular potential well at a heterojunction interface is lifted, and two-dimensional electronic gas in the channel is depleted or partially depleted.

When the device is turned off and a positive voltage on the drain electrode increases, a plurality of comb-finger-shaped p-type semiconductor blocks in contact with the source electrode will be gradually depleted, and fixed negative charges in the depletion region will deplete the two-dimensional electronic gas in the two-dimensional conductive channel. In this process, the two-dimensional electronic gas below each of the p-type semiconductor blocks will be depleted first. As the positive voltage of the drain source further increases, the two-dimensional electronic gas below a comb finger gap region of the comb-finger-shaped surface voltage-resistant structure connected to the source electrode will be gradually depleted.

If all semiconductor structures in the drift region are completely depleted when leaked voltage is high enough, the total amount of fixed positive charges generated by ionization is required to be equal to that of fixed negative charges. According to the principle, a doping concentration of the comb-finger-shaped p-type surface voltage-resistant structure may be appropriately set, so that the comb-finger-shaped p-type semiconductor blocks connected to the source electrode and the two-dimensional electronic gas below the comb finger gap region are depleted at the same time. In this way, a large depletion region is formed on the surface voltage-resistant structure between the source electrode and the drain electrode of the HEMT device as well as an extending region below the structure. The depletion region may bear higher voltage, directly resulting in that the voltage resistance of the device is improved.

When the device is conducted, the two-dimensional electronic gas below the comb finger gap region of the comb-finger-shaped p-type surface voltage-resistant structure connected to the source electrode through a metal wire is not affected by the plurality of p-type semiconductor blocks and has high electron concentration; therefore, the two-dimensional electronic gas is a favorable conductive path, ensuring that the on resistance of the device will not be significantly degraded due to the use of the voltage-resistant structure. On the other hand, during device design, the comb-finger-shaped p-type surface voltage-resistant structure connected to the source electrode only covers a small part of the drift region, so that the parasitic capacitance introduced by the surface voltage-resistant structure is relatively small. The device based on the voltage-resistant structure has smaller on resistance and additional capacitance, thereby having better high-frequency characteristic.

The present invention has the following beneficial effects:

the HEMT device according to the present invention realizes smaller on resistance and parasitic capacitance of the voltage-resistant structure while ensuring high breakdown voltage, and is suitable for the application fields with higher requirements on output power and working frequency.

### BRIEF DESCRIPTION OF THE DRAWINGS

FIG. I is a three-dimensional structural schematic diagram of the traditional n-channel HEMT device,

FIG. 2 is a first specific implementation of an n-channel HEMT device structure with a comb-finger-shaped p-type surface voltage-resistant structure connected to a source electrode according to the present invention.

FIG. 3 is a second specific implementation of an n-channel HEMT device structure with a comb-finger-shaped p-type surface voltage-resistant structure connected to a source electrode according to the present invention.

FIG. 4 is a top view of a second specific implementation of an n-channel HEMT device structure with a comb-finger-shaped p-type surface voltage-resistant structure connected to a source electrode according to the present invention.

FIG. 5 is a third specific implementation of an n-channel HEMT device structure with a comb-finger-shaped p-type surface voltage-resistant structure connected to a source electrode according to the present invention.

FIG. 6 is a top view of a third specific implementation of an n-channel HEMT device structure with a comb-finger-shaped p-type surface voltage-resistant structure connected to a source electrode according to the present invention.

FIG. 7 is a fourth specific implementation of an n-channel HEMT device structure with a comb-finger-shaped p-type surface voltage-resistant structure connected to a source electrode according to the present invention.

FIG. 8 is a top view of a fourth specific implementation of an n-channel HEMT device structure with a comb-finger-shaped p-type surface voltage-resistant structure connected to a source electrode according to the present invention.

FIG. 9 is a three-dimensional structural schematic diagram that a depletion region is formed below a plurality of p-type semiconductor blocks distributed in a comb finger shape in an n-channel HEMT device with a comb-finger-shaped p-type surface voltage-resistance structure connected to a source electrode.

FIG. 10 is a three-dimensional structural schematic diagram that a depletion region below a plurality of p-type semiconductor blocks distributed in a comb finger shape in an n-channel HEMT device with a comb-finger-shaped p-type surface voltage-resistance structure connected to a source electrode extends towards a region below a gap of the plurality of p-type semiconductor blocks and finally forms an approximately rectangular large depletion.

FIG. 11 is a three-dimensional structural schematic diagram that a GaN buffer layer is formed on an upper surface of a substrate according to the present invention.

FIG. 12 is a three-dimensional structural schematic diagram that an AlGaN buffer layer grows on an upper surface of a GaN buffer layer and forms a two-dimensional conductive channel according to the present invention.

FIG. 13 is a three-dimensional structural schematic diagram that a source electrode and a drain electrode which are in ohmic contact with a two-dimensional conductive channel are manufactured on an upper surface of an AlGaN barrier layer according to the present invention.

FIG. 14 is a three-dimensional structural schematic diagram that a gate electrode in Schottky contact with an AlGaN barrier layer is manufactured on an upper surface of the AlGaN barrier layer according to the present invention.

FIG. 15 is a three-dimensional structural schematic diagram that an upper surface of an AlGaN barrier layer between a gate electrode and a drain electrode with a p-type GaN layer maintaining a certain gap with a gate electrode and a drain electrode on two adjacent sides according to the present invention.

FIG. 16 is a three-dimensional structural schematic diagram that a plurality of p-type GaN blocks are formed on an etching p-type GaN layer according to the present invention.

FIG. 17 is a three-dimensional structural schematic diagram that a metal semi-contact region 13 is formed above one side, proximal to a gate electrode, of each of a plurality of p-type GaN blocks so as to be electrically connected to a source electrode according to the present invention.

FIG. 18 is a three-dimensional structural schematic diagram that a thin insulating medium is deposited at one end, proximal to a gate electrode, above a comb-finger-shaped p-type surface voltage-resistant structure connected to a source electrode, but does not cover a metal semi-contact region 13 according to the present invention.

FIG. 19 is a three-dimensional structural schematic diagram that a metal field plate is deposited above a thin insulating medium and a metal semi-contact region and is connected to a source electrode according to the present invention.

In the accompany drawings: substrate 1, buffer layer 2, barrier layer 3, gate electrode 4, source electrode 5, drain electrode 6, p-type semiconductor block 7, insulating medium 8, two-dimensional conductive channel 9, GaN buffer layer 10, AlGaN barrier layer 11, p-type GaN block 12, metal semi-contact region 13.

### DETAILED DESCRIPTION OF THE EMBODIMENTS

In order to make those skilled in the art better understand the solution and principle of the present invention, the present invention describes in detail with reference to the accompanying drawings and specific embodiments. The content of the present invention is not limited to any specific embodiments and does not represent that the present invention is the preferred embodiment, and general substitutions well known to those skilled in the part are covered within the protection scope of the present invention.

### Embodiment

The present invention provides an n-channel HEMT device with a comb-finger-shaped p-type surface voltage-resistant structure, including: a substrate 1, a buffer layer 2, a barrier layer 3, a gate electrode 4, a source electrode 5 and a drain electrode 6; the buffer layer 2 and the barrier layer 3 are sequentially arranged on the substrate 1; a two-dimensional conductive channel 9 is formed in an interface where the barrier layer 3 is in contact with the buffer layer 2; the source electrode 5 and the drain electrode 6 are arranged on two sides of the HEMT device respectively and are in ohmic contact with the two-dimensional conductive channel 9; a gate 4 is arranged between the source electrode 5 and the drain electrode 6, and the gate 4 is located on the barrier layer 3 and is in Schottky contact with the barrier layer 3; a plurality of p-type semiconductor blocks 7 distributed in a comb finger shape are arranged in a region, located between the gate electrode 4 and the drain electrode 6, on the barrier layer 3; each of the p-type semiconductor blocks extends along gate and drain directions, but is not in contact with the gate electrode 4 and the drain electrode 6 and maintains a proper spacing; a metal semi-contact region 13 is formed above one side, proximal to the gate electrode 4, of each of the p-type semiconductor blocks 7 to be electrically connected to the source electrode 5; and the plurality of p-type semiconductor blocks 7 jointly form a comb-finger-shaped surface voltage-resistant structure.

Since a gap is present between the comb-finger-shaped p-type surface voltage-resistant structures connected to the source electrode, the plurality of p-type semiconductor blocks 7 do not completely cover all regions above the barrier layer 3, and two-dimensional electronic gas below the uncovered region is not affected by the depletion effect of the plurality of p-type semiconductor blocks 7, thereby reducing on resistance and reducing the introduced additional capacitance.

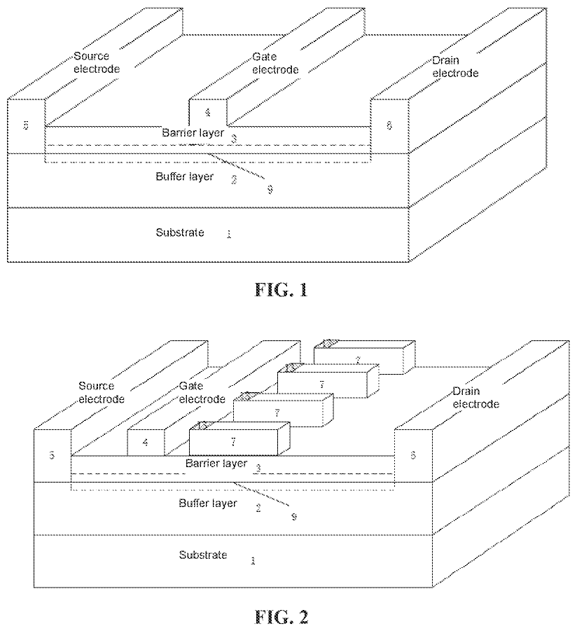

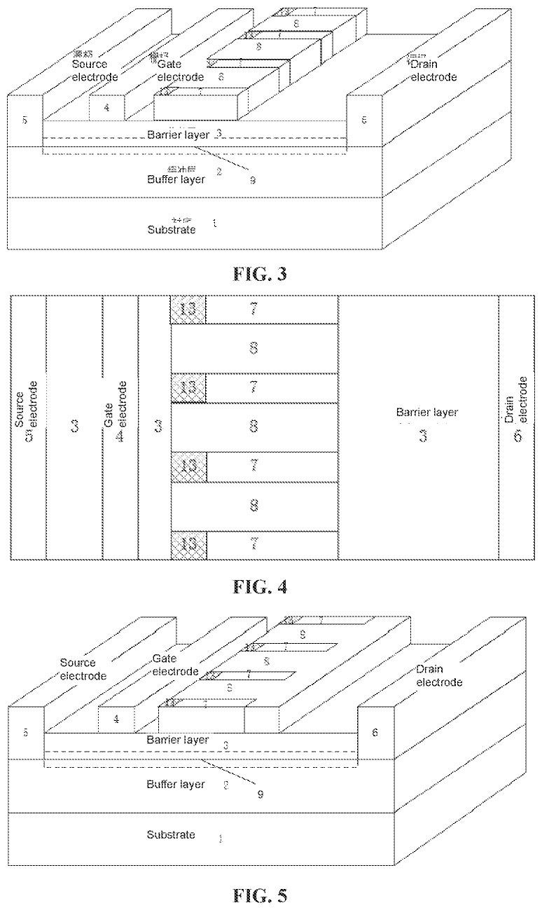

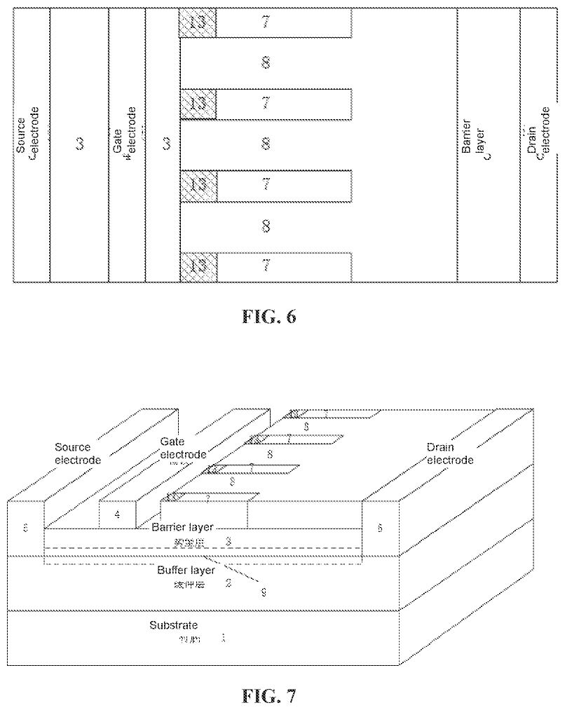

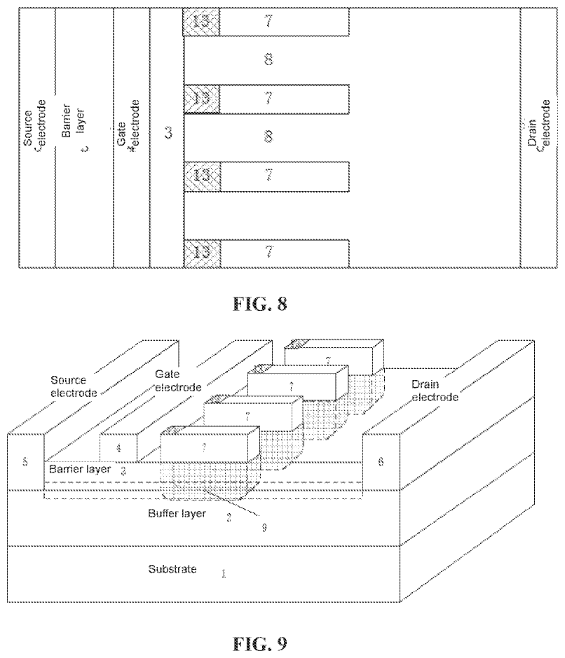

In some embodiments, an insulating medium 8 may be filled among the plurality of p-type semiconductor blocks 7, as shown in FIG. 3, and a top view is shown in FIG. 4. The plurality of p-type semiconductor blocks 7 and medium blocks 8 alternate with each other, and the insulating medium 8 may extend in a direction of the drain electrode 6, as shown in FIG. 5 and. FIG. 7 respectively, and top views are shown in FIG. 6 and FIG. 8 respectively. The plurality of p-type semiconductor blocks 7 are not directly connected to the gate electrode 4 and the drain electrode 6, any medium is not arranged between each of the p-type semiconductor blocks 7 and the drain electrode 6, as shown in FIG. 2; or the insulating medium 8 extends, but is not contact with the drain electrode 6, as shown in FIG. 5; and the insulating medium 8 extends to be in contact with the drain electrode 6, as shown in FIG. 7, so that the plurality of p-type semiconductor blocks 7 are indirectly connected to the drain electrode 6 through the insulating medium 8.

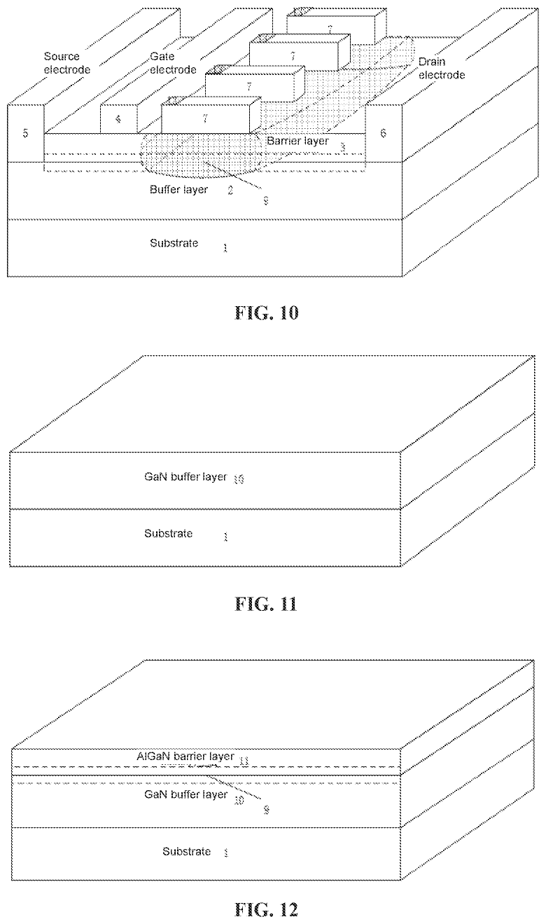

The working process of the present invention is described in detail with reference to FIG. 9 and FIG. 10.

For the traditional n-channel HEMT device, when high positive voltage is applied to the drain electrode, the drift region between the gate electrode and the drain electrode is difficult to complete deplete and voltage mainly drops in vicinity of the edge of the gate electrode, thus forming a large electric field peak to break down the device.

According to the present invention, a surface voltage-resistant structure formed by a plurality of p-type semiconductor blocks 7 distributed in a comb finger shape is arranged on a surface of a barrier layer 3 between a gate electrode 4 and a drain electrode 6 of an n-channel HEMT device. When the device is turned off, with the increase of a positive voltage of the drain electrode, two-dimensional electronic gas below the plurality of p-type semiconductor blocks 7 is depleted first; when the positive voltage of the drain electrode is high enough, a depletion region below each of the p-type semiconductor blocks expands to the surroundings, so that two-dimensional electronic gas in a region below a gap of the whole comb-finger-shaped surface voltage-resistant structure is also depleted, the depletion regions gradually expand until the depletion regions are connected to form an approximately rectangular large depletion, and in this process, the p-type semiconductor blocks are gradually depleted. The proper doping concentration of the p-type semiconductor blocks may ensure that the two-dimensional electronic gas in the p-type semiconductor blocks and the drift region are almost depleted at the same time, as shown in FIG. 10. On the basis that the depletion region of the drift region may play a role of resisting voltage, a voltage distribution region which originally drops on the edge of the gate electrode is greatly expanded, and the electric field peak of the drift region between the gate electrode and the drain electrode is effectively inhibited, thus increasing a breakdown voltage of the device and greatly improving the voltage resistance of the device.

FIG. 11 to FIG. 17 show a manufacturing method for an n-channel HEMT device. According to the embodiment, by taking a GaN-based n-channel device as an example, the preparation process of the GaN-based n-channel HEMT device in the embodiment is described in detail with reference to the accompanying drawings. The device is prepared by the following steps:

Step 1: a GaN buffer layer 10 is grown on a substrate 1, as shown in FIG. 11.

Step 2: an AlGaN barrier layer 11 is grown on the GaN buffer 10, and a two-dimensional conductive channel 9 is formed on an interface of the GaN buffer layer 10 and the AlGaN barrier layer 11, wherein two-dimensional electronic gas is present in the two-dimensional conductive channel 9, as shown in FIG. 12.

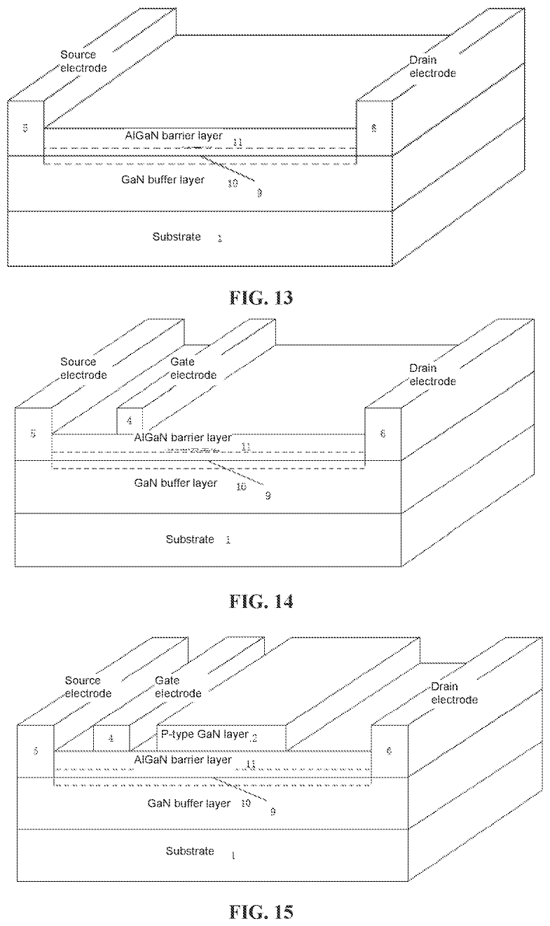

Step 3: a platform surface is etched to manufacture a device active region, a source electrode 5 and a source electrode 6 are prepared on the platform surface, and the source electrode 5 and the drain electrode 6 are in ohmic contact with the two-dimensional conductive channel 9 on the interface of the GaN buffer layer 10 and the AlGaN barrier layer 11 respectively, as shown in FIG. 13.

Step 4: a gate electrode 4 in Schottky contact with the AlGaN barrier layer 11 is manufactured above the AlGaN barrier layer 11, as shown in FIG. 14.

Step 5: a region between the gate electrode 4 and the drain electrode 6 above the AlGaN barrier layer 11 is covered with a p-type GaN layer until a proper thickness, as shown in FIG. 15.

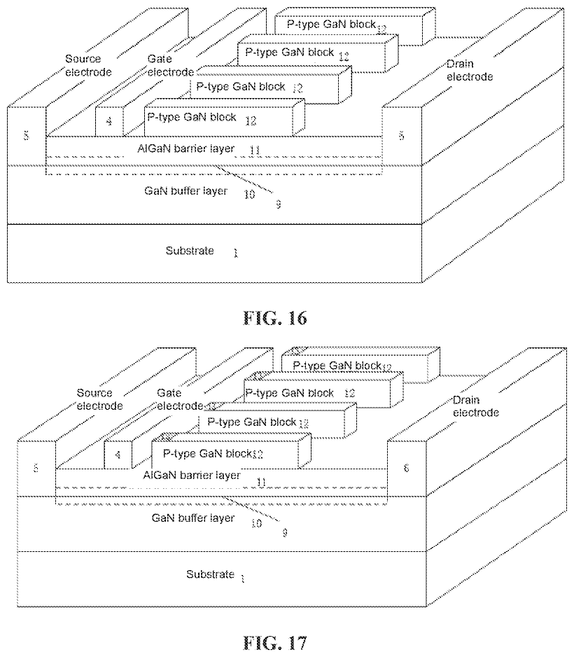

Step 6: the p-type GaN layer is subjected to pattern etching to a surface of the AlGaN barrier layer 11, so that a plurality of p-type GaN blocks 12 uniformly distributed and extending along gate and drain directions are formed above the AlGaN barrier layer 11, and the plurality of p-type GaN blocks 12 are not directly connected to the gate electrode 4 and the drain electrode 6, as shown in FIG. 16.

Step 7: a metal semi-contact region 13 is prepared on a top surface of each of a plurality of p-type GaN blocks 12, so as to realize electrical connection of the p-type GaN blocks 12 and the source electrode 5 through a metal wire. The subsequent process is consistent with an existing HEMT manufacturing process, and the GaN-based HEMT device of the embodiment is finally obtained, as shown in FIG. 17.

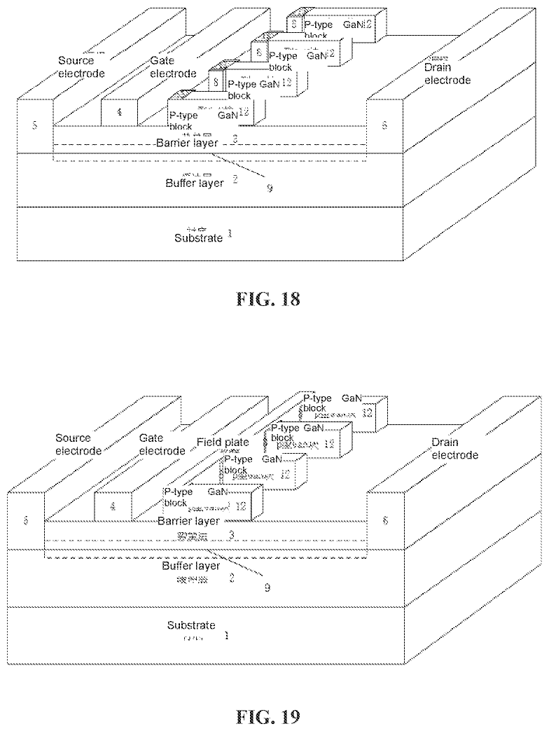

Furthermore, a method for manufacturing the n-channel HEMT device through combined use of the p-type surface voltage-resistant structure and the field plate is further illustrated with reference to FIG. 18 and FIG. 19.

According to the embodiment, by taking the GaN-based n-channel HEMT device as an example, the manufacturing process of the GaN-based n-channel Hl MT device in the embodiment is described with reference to the accompanying drawings. The device combines and applies the metal field plate and the comb-finger-shaped surface voltage-resistant structure, and is prepared by the following steps:

Step 1: a GaN buffer layer 10 is grown on a substrate 1, as shown in FIG. 11.

Step 2: an AlGaN barrier layer 11 is grown on the GaN buffer 10, and a two-dimensional conductive channel 9 is formed on an interface of the GaN buffer layer 10 and the AlGaN barrier layer 11, wherein two-dimensional electronic gas is present in the two-dimensional conductive channel 9, as shown in FIG. 12.

Step 3: a platform surface is etched to manufacture a device active region, a source electrode 5 and a source electrode 6 are prepared on the platform surface, and the source electrode 5 and the drain electrode 6 are in ohmic contact with the two-dimensional conductive channel 9 on the interface of the GaN buffer layer 10 and the AlGaN barrier layer 11 respectively, as shown in FIG. 13.

Step 4: a gate electrode 4 in Schottky contact with the AlGaN barrier layer 11 is manufactured. above the AlGaN barrier layer 11, as shown in FIG. 14.

Step 5: a region between the gate electrode 4 and the drain electrode 6 above the AlGaN barrier layer 11 is covered with a p-type GaN layer until a proper thickness, as shown in FIG. 15.

Step 6: the p-type GaN layer is subjected to pattern etching to a surface of the AlGaN barrier layer 11, so that a plurality of p-type GaN blocks 12 uniformly distributed and extending along gate and drain directions are formed above the AlGaN barrier layer 11, and the plurality of p-type GaN blocks 12 are not directly connected to the gate electrode 4 and the drain electrode 6, as shown in FIG. 16.

Step 7: one layer of thin insulating medium 8 is deposited at one end, proximal to the gate electrode 4, of the p-type surface voltage-resistant structure connected to the source electrode, and then the insulating medium on a top surface of the p-type GaN block 12 is removed to expose the metal semi-contact region 13, as shown in FIG. 18.

Step 8: a metal field plate is deposited above the thin insulating medium 8 and the metal semi-contact region 13, wherein the metal field plate is electrically connected to the source electrode 5, the subsequent process is consistent with an existing HEMT manufacturing process, and the GaN-based HEMT device of the embodiment is finally obtained, as shown in FIG. 19.

Various other specific modifications and combinations may be made by those of ordinary skill in the field without departing from the essence of the present invention according to technological enlightenments disclosed by the present invention, which are stilled in the protection scope of the present invention.

The above embodiments are only intended to exemplarily illustrate the principle and effect of the present invention, but not intended to limit the present invention. Any person skilled in the art can modify or change the above embodiments without departing from the spirit and scope of the present invention. Therefore, all equivalent modifications or changes made by those with ordinary knowledge in the art without departing the spirit and technical ideal disclosed by the present invention should still be covered within the claims of the present invention.

What is claimed is:

1. A high-voltage n-channel high electron mobility transistor (HEMPT) device, comprising: a substrate, a buffer layer arranged on an upper surface of the substrate, a barrier layer arranged on an upper surface of the buffer layer, a gate electrode arranged on an upper surface of the barrier layer, a source electrode and a drain electrode; wherein
the buffer layer and the barrier layer form a heterojunction on a contact interface of the buffer layer and the barrier layer, and a two-dimensional conductive channel is formed in a heterojunction interface;
the source electrode and the drain electrode are arranged on two upper sides of the barrier layer respectively and the source electrode and the drain electrode are in an ohmic contact with the two-dimensional conductive channel;
the gate electrode is arranged on the barrier layer between the source electrode and the drain electrode and is in a Schottky contact with the barrier layer;
the barrier layer between the gate electrode and the drain electrode is provided with a surface voltage-resistant structure, wherein the surface voltage-resistant structure comprises a plurality of p-type semiconductor blocks arranged in a comb finger shape, wherein
each of the plurality of p-type semiconductor blocks extending along gate and drain directions,
the plurality of p-type semiconductor blocks arranged in the comb finger shape are not in contact with the gate electrode and the drain electrode and are electrically connected to the source electrode, and
the plurality of p-type semiconductor blocks arranged in the comb finger shape are connected to the source electrode.

2. The high-voltage n-channel HEMT device according to claim 1, wherein an insulating medium is filled at least between adjacent p-type semiconductor blocks.

3. The high-voltage n-channel HEMT device according to claim 2, wherein the insulating medium and the drain electrode are separated from each other.

4. The high-voltage n-channel HEMT device according to claim 2, wherein
the insulating medium arranged between the adjacent p-type semiconductor blocks extends in a direction of the drain electrode and completely fill a gap between each of the plurality of p-type semiconductor blocks and the drain electrode,
the insulating medium surrounds the each of the plurality of p-type semiconductor blocks at one side, proximal to the drain electrode, of the each of the plurality of p-type semiconductor blocks, and
the insulating medium is in contact with the drain electrode.

5. The high-voltage n-channel HEMT device according to claim 1, wherein the surface voltage-resistant structure is configured to be used alone or in combination with a voltage-resistant structure, wherein the voltage-resistant structure comprises a field plate.

6. The high-voltage n-channel HEMT device according to claim 2, wherein the surface voltage-resistant structure is configured to be used alone or in combination with a voltage-resistant structure, wherein the voltage-resistant structure comprises a field plate.

7. The high-voltage n-channel HEMT device according to claim 3, wherein the surface voltage-resistant structure is configured to be used alone or in combination with a voltage-resistant structure, wherein the voltage-resistant structure comprises a field plate.

8. The high-voltage n-channel HEMT device according to claim 4, wherein the surface voltage-resistant structure is configured to be used alone or in combination with a voltage-resistant structure, wherein the voltage-resistant structure comprises a field plate.
